(19) United States
(12) Patent Application Publication
(10) Pub. No.: US 2014/0077338 A1
(43) Pub. Date: Mar. 20, 2014

(54) Si-Ge-Sn ON REO TEMPLATE

(71) Applicants: Radek Roucka, Mountain View, CA (US); Michael Lebby, Apache Junction, AZ (US); Scott Semans, Sunnyvale, CA (US)

(72) Inventors: Radek Roucka, Mountain View, CA (US); Michael Lebby, Apache Junction, AZ (US); Scott Semans, Sunnyvale, CA (US)

(21) Appl. No.: 13/619,736

(22) Filed: Sep. 14, 2012

(51) Int. Cl. H01L 29/12; H01L 21/20

(52) U.S. Cl. 257/613; 438/479; 257/E21.09; 257/E29.068

(57) ABSTRACT

An electronic device includes IV material grown on a silicon substrate. The device includes a crystalline silicon substrate and a rare earth structure epitaxially grown on the silicon substrate. The rare earth structure includes a layer of a rare earth oxide with electrical insulating characteristics so that the rare earth structure provides electrical insulation from the silicon substrate. A single crystal IV material film is epitaxially grown on the rare earth structure. The single crystal IV material film includes one of crystal lattice matching or crystal lattice mismatching the IV material film to the rare earth structure.

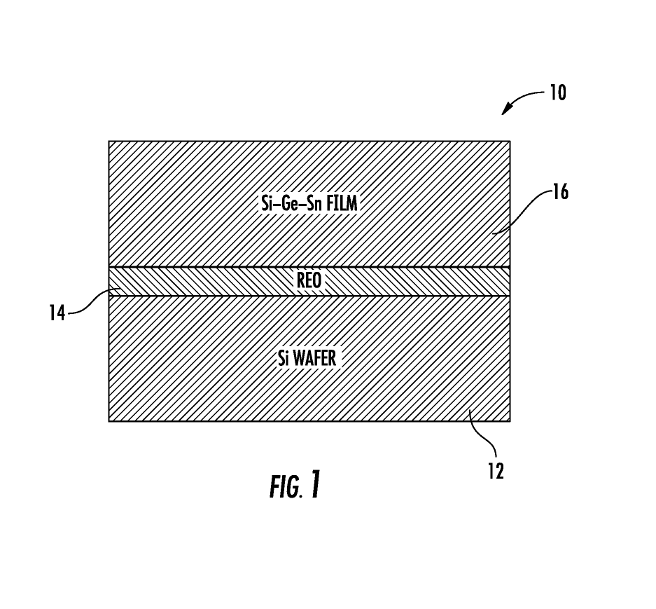

### FIELD OF THE INVENTION

This invention relates in general to the deposition of IV semiconductor material on silicon wafers and more specifically to a REO template or buffer between the IV material and the silicon substrate.

### BACKGROUND OF THE INVENTION

In the solar cell industry, it is known that germanium (Ge) is a desirable semiconductor material that absorbs substantial amounts of solar energy and is also useful in other photonic devices. In commercial solar cells, 3 junctions using III-V materials are deployed on a germanium substrate to emulate or match the solar spectrum. In these devices the higher energy of the solar spectrum (e.g. blue light) is absorbed by the high band gap materials, such as GaAs, InGaP and InGaAs. There are major problems with the use of germanium wafers. Germanium wafers are expensive and constitute approximately 50% of the total cost of the device. Also, germanium wafers are heavy and very brittle so that they are generally limited in size to less than 6″ in diameter. Further, because the wafers are brittle they must be relatively thick which due to the thermal conductivity issue creates a cooling problem. Presently, it has been found that the addition of tin (Sn) to germanium extends the absorption spectrum of a solar cell into lower energy light. However, efforts to grow sufficiently thick layers of GeSn or SiGeSn have been largely unsuccessful. In the prior art efforts to grow GeSn incorporating a constant mole fraction of SN on silicon substrates has resulted in the layers having a limited thickness because of cracking and stress fractures. As an example, a description of one such prior art method can be found in U.S. Pat. No. 7,589,003, entitled “GESN Alloys and Ordered Phases with Direct Tunable Bandgaps Grown Directly on Silicon”, issued Sep. 15, 2009.

It would be highly advantageous, therefore, to remedy the foregoing and other deficiencies inherent in the prior art.

Accordingly, it is an object of the present invention to provide new and improved methods for the growth of single crystal IV materials on single crystal silicon substrates.

It is another object of the present invention to provide new and improved methods of growing IV materials on silicon substrates with field screening therebetween.

It is another object of the present invention to provide new and improved IV materials on silicon substrates.

### SUMMARY OF THE INVENTION

Briefly, the desired objects and aspects of the instant invention are achieved in accordance with a preferred method of fabricating IV materials on a silicon substrate including epitaxially growing a rare earth structure on a single crystal silicon substrate and epitaxially growing a single crystal IV material film on the rare earth structure.

The desired objects and aspects of the instant invention are also realized in accordance with a specific method of fabricating IV materials on a silicon substrate including epitaxially growing a rare earth structure on the silicon substrate. The rare earth structure includes a layer of a rare earth oxide with electrical insulating characteristics so that the rare earth structure provides electrical insulation from the silicon substrate. The method also includes epitaxially growing a single crystal IV material film on the rare earth structure. The step of growing the single crystal IV material film includes either crystal lattice matching the IV material to the rare earth structure or crystal lattice mismatching the IV material film to the rare earth structure.

The desired objects and aspects of the instant invention are also realized in accordance with a specific embodiment of a device including IV material grown on a silicon substrate using a rare earth structure epitaxially grown on the silicon substrate and the single crystal IV material film epitaxially grown on the rare earth structure.

The desired objects and aspects of the instant invention are further realized in accordance with a specific embodiment of a device including IV material grown on a silicon substrate. The device includes a rare earth structure epitaxially grown on the silicon substrate, the rare earth structure including a layer of a rare earth oxide with electrical insulating characteristics so that the rare earth structure provides electrical insulation from the silicon substrate. A single crystal IV material film epitaxially grown on the rare earth structure includes either crystal lattice matching or crystal lattice mismatching the IV material film to the rare earth structure.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawing in which the single FIGURE illustrates a simplified layer diagram of an IV film on a silicon substrate, in accordance with the present invention.

### DETAILED DESCRIPTION OF THE DRAWING

Turning to the single FIGURE a simplified layer diagram is illustrated of a REO/IV template 10 on a silicon substrate 12. Substrate 12 includes single crystal silicon which, it will be understood, is or may be a standard well know single crystal silicon wafer or portion thereof generally known and used in the semiconductor industry. Single crystal silicon substrate 12, it will be understood, is not limited to any specific crystal orientation but could include <111> silicon, <110> silicon, <100> silicon or any other orientation or variation known and used in the art, such as miscuts with nominal value between 0 and 10° in any direction.

A rare earth oxide (REO) structure 14 (shown for convenience as a single layer) is grown directly on the surface of substrate 12 using any of the well known growth methods, such as MBE, MOCVD, PLD (pulsed laser deposition), sputtering, ALD (atomic layer deposition), or any other known growth method for thin films. Further, the growth method used will generally be used for all additional layers and may conveniently be employed to grow the entire structure in a continuous process sometimes referred to herein as performed within a one wafer single epitaxial process. REO structure 14 may be considered one or more single crystal or crystalline layers or a single layer of single crystal or crystalline material with a plurality of sub-layers, either of which will be referred to herein for convenience of understanding as a “REO structure”. Throughout this disclosure whenever rare earth materials are mentioned it will be understood that “rare earth” materials are generally defined as any of the lanthanides as well as scandium and yttrium.

REO structure 14 is specifically designed or engineered to gradually adjust from the crystal lattice of silicon substrate 12 to approximately the crystal lattice of a IV film 16 positioned on the surface of REO structure 14. This gradual adjustment of the crystal lattice between the interface with substrate 12 and the interface with film 16 is generally designed to closely or approximately match the lattice spacing between adjacent layers or to provide a close match or a desired amount of mismatch in lattice spacing. For example, film 16 can be unstressed or stressed, either compressive or tensile, depending on the selection or engineering of the rare earth composition in structure 14, the type of device being fabricated (e.g. photovoltaic, photonic, etc.) and the specific IV material in film 16.

While film 16 is illustrated as a single layer for convenience, it will be understood that it may include from one to several layers of IV material and each layer may be different and the layers may have different thicknesses to accomplish different purposes. Generally, the IV material will include SiGeSn, GeSn, Ge or any combinations including any of these materials. Further, when Sn is included with Ge, the Sn may be graded in some fashion through the layer to enhance growth, improve the crystalline quality, and provide for thicker layers of material. Grading of Sn through layers of Ge is explained in more detail in a U.S. copending patent application entitled “Graded GeSn on Silicon”, bearing Ser. No. 13/593,305, filed 23 Aug. 2012, and incorporated herein by reference.

It will be understood that IV film 16 and REO structure 14 generally serve as template 10 for the further growth of layers forming a device on or as part of IV film 16. See for example devices described in the copending patent application described above. In many instances it is desirable to electrically shield the devices from the silicon substrate. There is no known insulator material in the prior art which can be an electrical barrier and a template for the epitaxial growth of IV material on a silicon substrate. One specific advantage of REO structure 14 of the present invention is to provide field screening or electrical isolation between IV film 16 and silicon substrate 12. Many of the rare earth oxides provide very good electrical insulation or dielectric characteristics. Incorporating any of the rare earth oxides with dielectric or electrical insulating properties provide field screening or electrical isolation between IV film 16 and silicon substrate 12. The electrical isolation between IV film 16 and silicon substrate 12 opens the structure to the formation of high speed logical circuits, for example, in which it is required that the active component of the device is insulated from the wafer/substrate.

Thus, new and improved methods for the growth of single crystal IV materials on single crystal silicon substrates have been disclosed. Also, the new and improved methods of growing IV materials on silicon substrates include field screening therebetween. Further, new and improved templates of REO/IV materials for the growth of devices on silicon substrates have been disclosed.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of fabricating IV materials on a silicon substrate comprising the steps of:
providing a crystalline silicon substrate;
epitaxially growing a rare earth structure on the silicon substrate; and
epitaxially growing a single crystal IV material film on the rare earth structure.

2. A method as claimed in claim 1 wherein the step of epitaxially growing the single crystal IV material film includes one of crystal lattice matching or crystal lattice mismatching the IV material film to the rare earth structure.

3. A method as claimed in claim 1 wherein the step of epitaxially growing the single crystal IV material film includes growing at least a layer including GeSn using a grading profile to grade Sn through the layer.

4. A method as claimed in claim 3 wherein the step of growing at least the layer including GeSn includes growing the graded single crystal GeSn layer with a thickness in a range of approximately 3 μm to approximately 5 μm.

5. A method as claimed in claim 1 wherein the step of epitaxially growing the rare earth structure includes incorporating a rare earth oxide with electrical insulating characteristics so that the single crystal IV material film is electrically insulated from the silicon substrate.

6. A method as claimed in claim 1 wherein the step of epitaxially growing the single crystal IV material film includes growing at least a layer including one of SiGeSn, GeSn, Ge or any combinations including any of these materials.

7. A method of fabricating IV materials on a silicon substrate comprising the steps of:
providing a crystalline silicon substrate;
epitaxially growing a rare earth structure on the silicon substrate, the rare earth structure including a layer of a rare earth oxide with electrical insulating characteristics so that the rare earth structure provides electrical insulation from the silicon substrate; and
epitaxially growing a single crystal IV material film on the rare earth structure, the single crystal IV material film including one of crystal lattice matching or crystal lattice mismatching the IV material film to the rare earth structure.

8. A method as claimed in claim 7 wherein the step of epitaxially growing the single crystal IV material film includes growing at least a layer including GeSn using a grading profile to grade Sn through the layer.

9. A method as claimed in claim 8 wherein the step of growing at least the layer including GeSn includes growing the graded single crystal GeSn layer with a thickness in a range of approximately 3 μm to approximately 5 μm.

10. A method as claimed in claim 7 wherein the step of epitaxially growing the single crystal IV material film includes growing at least a layer including one of SiGeSn, GeSn, Ge or any combinations including any of these materials.

11. A device including IV material grown on a silicon substrate comprising:
a crystalline silicon substrate;
a rare earth structure epitaxially grown on the silicon substrate; and
a single crystal IV material film epitaxially grown on the rare earth structure.

12. A device as claimed in claim 11 wherein the single crystal IV material film includes one of being crystal lattice matched or crystal lattice mismatched to the rare earth structure.

13. A device as claimed in claim 11 wherein the single crystal IV material film includes at least a layer including GeSn with the Sn being graded through the layer.

14. A device as claimed in claim 13 wherein the layer including GeSn has a thickness in a range of approximately 3 μm to approximately 5 μm.

15. A device as claimed in claim 11 wherein the rare earth structure includes a rare earth oxide with electrical insulating characteristics so that the single crystal IV material film is electrically insulated from the silicon substrate.

16. A device as claimed in claim 11 wherein the single crystal IV material film includes at least a layer including one of SiGeSn, GeSn, Ge or any combinations including any of these materials.

17. A device including IV material grown on a silicon substrate comprising:
a crystalline silicon substrate;
a rare earth structure epitaxially grown on the silicon substrate, the rare earth structure including a layer of a rare earth oxide with electrical insulating characteristics so that the rare earth structure provides electrical insulation from the silicon substrate; and
a single crystal IV material film epitaxially grown on the rare earth structure, the single crystal IV material film including one of crystal lattice matching or crystal lattice mismatching the IV material film to the rare earth structure.

18. A device as claimed in claim 17 wherein the single crystal IV material film includes at least a layer including GeSn with graded Sn through the layer.

19. A device as claimed in claim 18 wherein the layer including GeSn has a thickness in a range of approximately 3 μm to approximately 5 μm.
